(19) United States
(12) Patent Application Publication
(10) Pub. No.: US 2025/0379642 A1
(43) Pub. Date: Dec. 11, 2025

(54) mmWave Passive Beamforming Repeaters for Millimeter Wave

(71) Applicant: The Regents of the University of California, Oakland, CA (US)

(72) Inventors: Omid Salehi-Abari, Oakland, CA (US); Tianxiang Li, Oakland, CA (US); Mohammad Hossein Mazaheri Kalahrody, Oakland, CA (US)

(73) Assignee: The Regents of the University of California, Oakland, CA (US)

(21) Appl. No.: 19/232,682

(22) Filed: Jun. 9, 2025

Related U.S. Application Data
(60) Provisional application No. 63/657,521, filed on Jun. 7, 2024.

(51) Int. Cl. H04B 7/145; H01Q 1/24; H01Q 3/32; H01Q 13/02; H03F 3/19

(52) U.S. Cl. CPC H04B 7/145; H01Q 1/246; H01Q 3/32; H01Q 13/02; H03F 3/19; H03F 2200/294

(57) ABSTRACT

In an embodiment of the invention, a passive beamforming wireless signal repeater includes a Rotman lens having a plurality of input ports and a corresponding plurality of output ports, each output port corresponding to an input port, each input port configured to receive a signal from an uplink antenna and apply a phase change to the signal before emitting the signal from the corresponding output port, and a frequency scanning antenna (FSA) structure comprising a first plurality slots of varying lengths configured to apply a different phase shift at each radiating slot and cause the radiated signals to combine constructively in a certain direction, the FSA configured to receive a signal from the Rotman lens and direct an output signal in a direction determined by the frequency of the signal.

### CROSS-REFERENCE TO RELATED APPLICATIONS

The current application claims priority under 35 U.S.C. 119 (e) to U.S. Provisional Patent Application Ser. No. 63/657,521, entitled “mmWave Passive Beamforming Repeaters”, filed Jun. 7, 2024. The disclosure of U.S. Provisional Patent Application No. 63/657,521 is hereby incorporated by reference in its entirety for all purposes.

### STATEMENT OF FEDERALLY SPONSORED RESEARCH

This invention was made with government support under 2238245 awarded by the National Science Foundation. The government has certain rights in the invention.

### FIELD OF THE INVENTION

The present invention relates generally to wireless signal repeaters and more specifically to passive beamforming structures which can be suitable for mmWave frequencies.

### BACKGROUND OF THE INVENTION

Advancements in computing have enabled emerging applications such as telesurgery, robot automation, holographic tele presence, and extended reality, which require gigabit per-second throughput, sub-millisecond latency, and highly reliable wireless connectivity. Millimeter wave (mmWave) technology can enable such connectivity by operating over a large bandwidth in the high-frequency spectrum bands (24 GHz and above) to offer high data throughput and low latency. In particular, high-data-rate mmWave networks typically work reliably only when there is a clear line-of-sight (LOS) path between users and base stations. Due to the short wavelength and high directionality of mmWave signals, mmWave networks have limited coverage and are highly susceptible to blockage. Unfortunately, due to this problem, mmWave networks have not been able to scale and become ubiquitous. Past work has proposed mmWave repeaters and intelligent surfaces to solve this issue by rerouting signals around blockages or utilizing phased arrays. However, these solutions are expensive and complex to build, consume high power, or/and require constant feedback from the network to operate since they use active techniques for beam steering.

### SUMMARY OF THE INVENTION

In several embodiments of the invention, a passive beamforming wireless signal repeater includes a Rotman lens having a plurality of input ports and a corresponding plurality of output ports, each output port corresponding to an input port, each input port configured to receive a signal from an uplink antenna and apply a phase change to the signal before emitting the signal from the corresponding output port, and a frequency scanning antenna (FSA) structure comprising a first plurality slots of varying lengths configured to apply a different phase shift at each radiating slot and cause the radiated signals to combine constructively in a certain direction, the FSA configured to receive a signal from the Rotman lens and direct an output signal in a direction determined by the frequency of the signal.

In another embodiment of the invention, the uplink antenna is a horn antenna.

In a further embodiment of the invention, the Rotman lens and the FSA are both formed on a PCB substrate.

An additional embodiment of the invention also includes a low noise amplifier (LNA) connected to each uplink antenna.

In more embodiments of the invention, the LNA is a unidirectional LNA.

In still more embodiment of the invention, the LNA is a bidirectional LNA.

An additional embodiment of the invention also includes a first unidirectional LNA connected to each uplink antenna in an input direction and a second unidirectional LNA in an output direction.

In another embodiment of the invention, a second plurality of slots on a back surface of FSA opposite of the first plurality of slots.

In a further embodiment of the invention, the Rotman lens includes eight input ports.

In more embodiments of the invention, the signal repeater implements a channel matrix of H=GK, where K is the matrix of channels between a base station and the signal repeater's uplink antennas, and is G the matrix of channels between the repeater and the user devices.

In still more embodiment of the invention, the base station implements a precoding matrix, to the inverse of GK.

In another embodiment of the invention, the Rotman lens and the FSA combine to direct the output signal in two dimensions.

### DESCRIPTION OF THE FIGURES

FIG. 1A illustrates a frequency scanning antenna (FSA) in accordance with embodiments of the invention.

FIG. 1B illustrates an FSA transmitting a beam toward a direction in accordance with embodiments of the invention.

FIG. 2 illustrates an FSA having varying slots in accordance with embodiments of the invention.

FIG. 3A illustrates a Rotman lens in accordance with embodiments of the invention.

FIG. 3B illustrates a Rotman lens transmitting a beam toward a direction in accordance with embodiments of the invention.

FIG. 4A illustrates a Rotman lens at mmWave integrate with an FSA design on the same PCB substrate in accordance with embodiments of the invention.

FIG. 4B illustrates an example circuit layout in accordance with embodiments of the invention.

FIG. 5A illustrates an example of a typical 2×2 MU-MIMO system.

FIG. 5B illustrates a passive repeater used in a MU-MIMO system in accordance with embodiments of the invention.

FIG. 6 illustrates steps in end-to-end beam alignment when a passive repeater is deployed in accordance with some embodiments of the invention.

FIG. 7A shows the SNR of a user device versus distance of the user device from the repeater in accordance with some embodiments of the invention.

FIG. 7B shows the SNR of the user device versus distance of the user device from the repeater in accordance with some embodiments of the invention.

FIG. 8 illustrates an example evaluation setup where the coverage of a passive repeater in accordance with some embodiments of the invention.

FIG. 9 illustrates different environments where a passive repeater may be deployed in accordance with embodiments of the invention.

### DETAILED DISCLOSURE OF THE INVENTION

Passive beamforming repeaters in accordance with embodiments of the invention are disclosed. Such repeaters may be utilized for many different frequencies, but can be particularly suitable for mm Wave frequencies, which have relatively short range due to path loss and blockage. Existing mmWave networks face a major problem which prevents them from becoming scalable and ubiquitous. mmWave networks have a very limited coverage since they use high-frequency signals which experience a huge path loss. To compensate for this loss, current mmWave systems use directional antennas and focus the signal power in a narrow beam. Hence, communication between two nodes is possible when their beams are aligned. In addition to the drawbacks of complexity and high power consumption mentioned further above, prior designs typically require feedback from the access point and client to the base station concerning the channel characteristics. Existing mmWave relays and repeaters either support only a single user or/and require phased arrays which are complex, expensive, and consume significant amount of power.

Passive beamforming repeaters to form and steer beams in accordance with embodiments of the invention can consume low power with a passive design, be cost effective with a low number of components (circuits and amplifiers), and require less feedback from the access point and client. Further embodiments of the invention can accommodate multiple users or channels.

### Overall Architecture

One dimensional (1D) beam steering can be accomplished using a frequency scanning antenna (FSA). An FSA is a passive structure which focuses and transmits (or receives) a signal toward a direction, where the direction of the signal depends on the frequency of its input signal. In many embodiments of the invention, a repeater can be designed using both a Rotman lens and a frequency scanning antenna (FSA) to be steerable in two dimensions (2D), e.g., one vertical and one horizontal, although any arbitrary direction is applicable. The Rotman lens can steer the beam in one dimension, while the FSA can steer the beam in another dimension.

### Frequency Scanning Antenna (FSA)

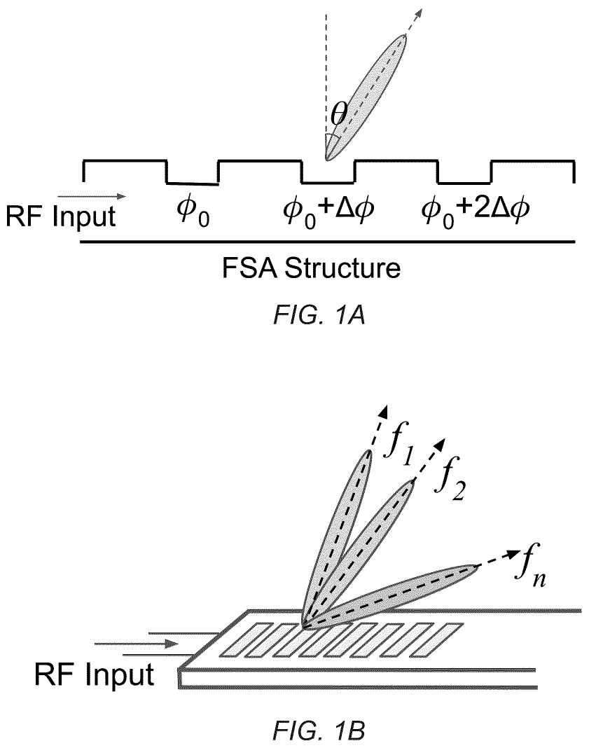

FSA isa technique typically used in radar imaging and weather forecast to perform measurements. It is a passive structure which focuses and transmits (or receives) a signal toward a direction, where the direction of the signal depends on the frequency of its input signal, as shown in FIG. 1A. One can design an FSA on PCB that includes a substrate with many radiating elements (slots). When a signal is fed to the input of the FSA structure, the signal gradually leaks into space through these radiating slots. However, the signal experiences a different phase shift at each radiating slot, which causes the radiated signals to combine constructively in a certain direction, as shown in FIG. 1A. Since signals of different frequencies have different wavelengths, they experience different amounts of phase shift at each radiating slot. Hence, FSA forms a transmitting beam toward a direction which depends on the frequency of the signal as shown in FIG. 1B. Note, FSA can perform the same for receiving a signal too.

An FSA can provide a passive way to create multiple beams simultaneously when the signal contains multiple channels with different center frequencies for a passive beamforming repeater in accordance with embodiments of the invention. Moreover, the repeater can steer each beam based on the shift in its signal center frequency, without relying on any phase shifters or active components. Hence, by integrating an FSA on a repeater, the repeater can create multiple beams toward receivers, simultaneously. In particular, when the base station transmits/receives a signal consisting of multiple frequency channels (e.g., centered at f₁ to fₙ) to/from the repeater, the FSA on the repeater is able to passively split the different frequency channels into separate high-gain beams to cover different areas on the ground. Compared to phased arrays, this design utilizes lower power, lower complexity, and lower cost for beam steering and creating multiple beams simultaneously since it is purely based on a passives structure. Moreover, it does not require any processor or feedback from the base station (or the client) since they can steer the repeater's beam themselves by changing the frequency channel. Further details are described below on how this design would enable a repeater which can be easily deployed without any need for a change or feedback to the base station or client.

Traditional mmWave FSA designs have multiple limitations can be addressed in embodiments of the invention. First, previous designs require a large bandwidth to achieve a wide range of steering angles. Unfortunately, such a large bandwidth is not available in the 5G mmWave band. Second, they only support beam scanning from 0° to positive angles. This is due to the fact that the wave traveling in the structure only provides positive phase shift between consecutive radiating elements. Therefore, an FSA utilized in repeaters according to embodiments of the invention (a) require smaller bandwidth for beam steering and (b) can cover negative angles.

To achieve a reasonably large range for beam steering angle while using a small frequency change, large phase changes should be created between the FSA radiating slots. To achieve this, certain embodiments of the invention reduce the speed of the traveling wave inside the FSA. To control the speed of the wave, an approach can build on a technique used in meta-materials, known as Spoof Surface Plasmon. In several embodiments of the invention, slots are placed on the back of the FSA antenna. These back plate slots do not radiate the signal, but they act as a speed bump to reduce the wave velocity in the structure. Reducing the wave velocity provides a higher phase variation with frequency change, enabling larger beamsteering angle in a smaller bandwidth.

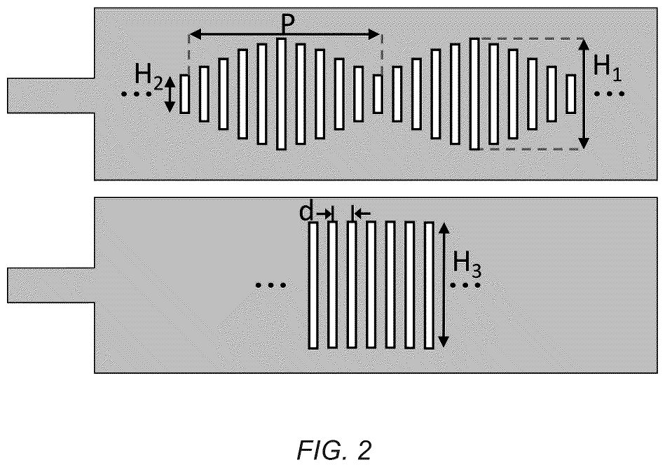

To enable beam steering for negative angles, certain embodiments of the invention use modulated periodic slots on the top plate of our FSA. As shown in FIG. 2, the sizes of the radiating slots can vary along the FSA structure in several embodiments. This periodicity in structure provides spatial amplitude modulation (AM) (as distinguished from temporal AM in wireless communications) of the wave in the FSA structure, which creates infinite number of space harmonics. However, only the first harmonic radiates. This space harmonic creates negative phases for lower frequencies while positive phase for higher frequencies. Therefore, at the lower part of the frequency band, the FSA beam is pointing toward negative angles, while at higher frequencies, the beam is steered toward positive angles.

The design parameters to control the characteristics of the FSA shown in FIG. 2 are H₁, H₂, H₃, P, and d. As mentioned above, the slots in the back plane of the FSA do not radiate the signal. Rather, they are used to decrease the wave velocity. The proper wave velocity can be achieved by adjusting the value of H₃ and d. For the slots in the top plane, the lengths of the slots are modulated. The period (P) and the amplitude of slots (H₁, H₂) define the backward and forward scanning range. Finally, the total number of slots and the length of the structure define the 3 dB beam width of the FSA.

The FSA can receives a signal from the Rotman lens and transmit the signal in a direction depending on the frequency of the input signal. The Rotman lens may provide a signal where there is a different phase shift at each radiating slot of the FSA, such that the radiated signals combine constructively in a certain direction. In additional embodiments, an FSA may receive a signal from a direction. In several embodiments, an FSA can be fabricated using a printed circuit board (PCB), which may be on the same PCB substrate as the Rotman lens. The illustrated FSA antenna includes top and bottom layers with modulated and equal length periodic slots, although other designs of an FSA antenna having different dimensions may be utilized in others embodiments of the invention as appropriate to a particular application. Suitable dimensions for frequencies of interest may be determined, for example, by simulation.

### Rotman Lens

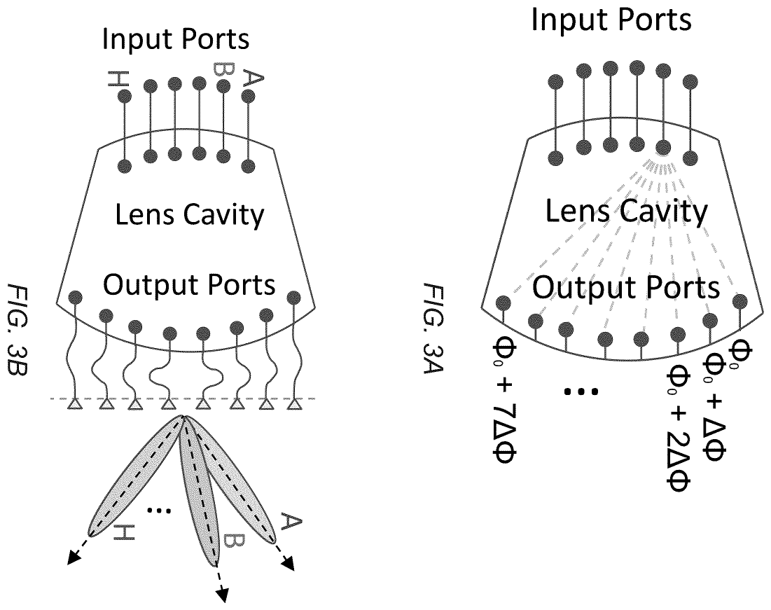

As discussed above, an FSA can act as a passive structure for beamforming and steering in different directions. However, since the structure is a linear array of emitting elements, it forms beams only along a single dimension. To support multiple users in an area, a repeater system in accordance with embodiments of the invention should generate beams in two dimensions (2D). Therefore, many embodiments of the invention integrate the FSA design into a Rotman lens. Rotman lens is a passive structure traditionally used in radar systems to detect targets in different directions. The basic structure of a Rotman lens is shown in FIG. 3A. It includes a number of input ports, a lens cavity, and a number of output ports which are typically connected to individual antennas. Each output port corresponds to an input port. This structure can create a beam where its direction depends on which input port is used to feed the signal. The lens cavity, which can be fabricated using a PCB, is designed such that it adds specific phase changes to the signal as it propagates from each input port of the Rotman lens to its corresponding output port.

Due to the shape of this structure, the amount of these phase changes depend on which input port is used for feeding the signal. Therefore, the antennas connected to the output ports of the Rotman lens emit the signal with different phases, creating a beam toward a direction that depends on which input port is used as shown in FIG. 3B. While this describes how a Rotman lens works for transmitting signals, it also works the same for receiving.

While the illustrated embodiment shows eight sets of ports, other embodiments of the invention may have different numbers of ports as appropriate to a particular application. More ports allow a narrower beam and longer range. In several embodiments, a Rotman lens can be fabricated using a printed circuit board (PCB).

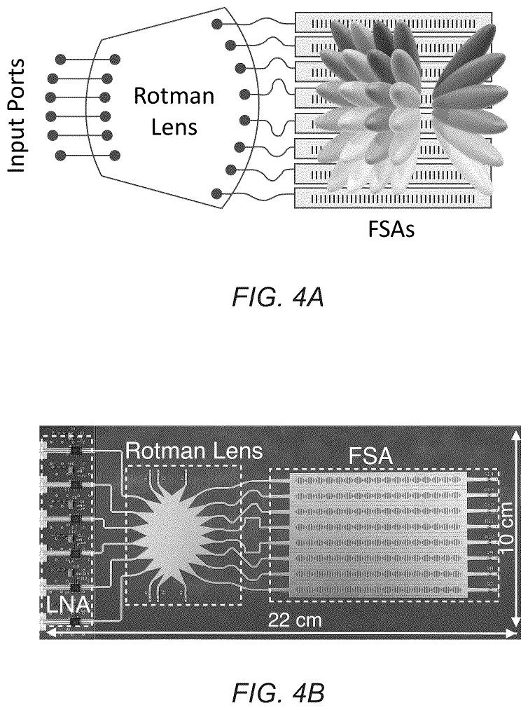

Each of an FSA and Rotman lens enables beam steering in only 1D. However, FSA steers the beam with change of frequency, and the Rotman lens steers the beam with change of input port. Hence, to enable 2D passive beamforming and steering, embodiments of the invention integrate a Rotman lens at mmWave with an FSA design on the same PCB substrate, as shown in FIG. 4A. An example circuit layout is shown in FIG. 4B. In particular, this design connects each output port of the Rotman lens to the input of a separate FSA structure instead of just a typical antenna. As will be described further below, this structure enables 2D beamforming and steering. When a signal with a particular frequency is fed into one of the Rotman lens input ports, all FSAs receive the signal with different phase shifts created by Rotman lens cavity. Since the signal frequency is the same for all FSAs, they all create beams toward the same direction in 1D. However, since their signals have different phases caused by Rotman lens, their 1D beams are combined and create a 2D beam toward a specific direction. This novel structure enables passive beamforming and steering in 2D. In other words, by changing the frequency of the signal, the beam can be steered in one dimension, and by changing the input port the signal is fed into the Rotman lens, the beam can be steered in the other dimension. Thus, create multiple beams can be created simultaneously in 2D by feeding signals of different frequencies to different ports. Selectively turning on and off each port using switches on the Rotman lens can enable use of this structure in a repeater. One solution is to use feedback from the base station and client. Another solution is to have the base station steer its narrow beam only toward one of the input ports of the Rotman lens. A further solution as discussed below is to combine MU-MIMO and an FSA-Rotman lens structure to support multiple users in both dimensions.

### Multi-User and MU-MIMO

Referring again to FIG. 4A, each input port of a passive structure (FSA and Rotman lens) can be connected to a horn antenna. Such a design enables a repeater which can receive/transmit the signal from/to a base station using horn antennas and transmit/receive it to/from the clients using beams created by the passive structure. Horn antennas may be used for backhaul (i.e., the link between the repeater and base station) since base stations and repeaters are typically fixed in place at a location. Hence, they only need to perform the beam alignment process once, during the manual installation of the repeater. There are other alternative approaches for the backhaul link as will be discussed further below. To support multi-user communication and steer its beam, a repeater in accordance with embodiments of the invention can divides users into different frequency channels in one dimension using FSA beams. Hence, they can communicate simultaneously using Frequency Division Multiple Access (FDMA). To support multiple users in the other dimension, the repeater can divides users into different beams created by the Rotman lens and use Multi-User Multiple Input Multiple Output (MU-MIMO), which is already provided in most mmWave base stations (such as 5G).

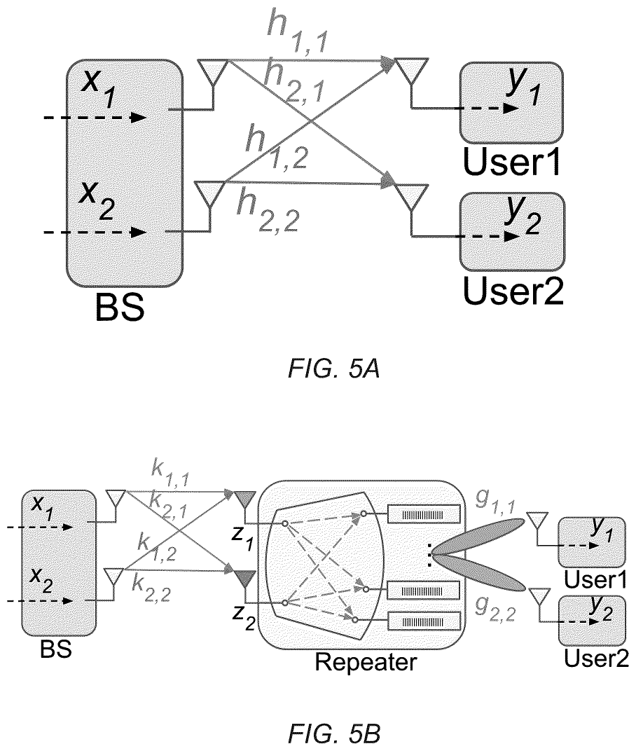

MU-MIMO enables a base station to simultaneously communicate to multiple users over the same frequency channel. In a typical MU-MIMO system (when there is no repeater), the vector of received signals by users, y, can be written as: y=HWx, where H is the matrix of channels between the base station and users, W is the precoding matrix, and x is the vector of the data sent by the base station. FIG. 5A shows an example of a typical 2×2 MU-MIMO system. In these systems, the channel matrix H is measured in the channel estimation stage, and then the precoding matrix W is set to the inverse of the channel matrix. Hence, by transmitting Wx instead of x, the base station can simultaneously transmit multiple data streams while each user receives only its own data stream.

When a repeater in accordance with embodiments of the invention is used in a MU-MIMO system as shown in FIG. 5B, the only difference would be the channel matrix. The signals transmitted by the base station antennas will be first received by the backhaul antennas, and then they will be forwarded to users through separate beams created by the passive structure. Hence, the channel matrix will be H=GK, where K is the matrix of channels between the base station and the repeater's backhaul antennas, and G is the matrix of channels between the repeater and the user devices. Note, G is a diagonal matrix since the signal received at each backhaul antenna of the repeater creates a separate beam towards each user as shown in FIG. 5B. To obtain the channel matrices, the base station and client can perform their standard channel estimation through the reciprocal exchange of reference signals. For example, in the downlink, when the base station sends reference signal on a specific frequency channel, it will be received by the repeater and re-sent to different spatial directions. User devices in each spatial direction will receive the signal, estimate the channel and send feedback. The same channel estimation process can be done for each frequency channel. This works similarly for uplink channel estimation.

To enable MU-MIMO, the base station can set the precoding matrix W to the inverse of GK. Note that as the repeater is transparent to the base station and performs no processing on the signals, during the MU-MIMO channel estimation stage, the base station and users can measure GK as the channel matrix between the base station and users, and use it to compute the precoding matrix. The signals received by the backhaul antennas of the repeater can be presented as z=KWx, where, W=(GK)⁻¹. Therefore, we can show that z=G⁻¹x. Note since G is a diagonal matrix, its inverse is also diagonal. This enables MU-MIMO from the base station to the repeater's backhaul antennas. The signal received at each repeater's backhaul antenna is directed toward a user device via a beam using the repeater. Hence, the base station can support MU-MIMO to the user devices without any additional complexity on the repeater. Finally, the discussion above focuses on the downlink as several implementations of the repeater in accordance with embodiments of the invention are uni-directional. This follows when LNAs used in the design are uni-directional. Hence, to send the channel estimation back to the base station from the user device or/and to support two-way communication, additional embodiments of the invention may utilize bidirectional LNAs or deploy two mmXtend repeaters (one in each direction).

### End-to-End Link

Passive repeaters in accordance with many embodiments of the invention may establish an end-to-end communication link between the base station (BS) and the user device(s). In a typical mmWave network, the BS and the user device perform beam searching to find the best direction for their beams to enable a communication path between the BS and the user device. This path is typically the direct line-of-sight (LOS) path between them. Next is explained how this process is done in today's 5G networks, and then describe how passive repeaters in accordance with embodiment of the invention can seamlessly be integrated without interfering with the standard process.

In the conventional 5G mmWave beam alignment process, the BS sends groups of synchronization signals periodically in multiple spatial directions and different frequency channels, to detect user devices in different areas. On the user side, the user device initiates a beam sweeping process using a wide beam and scans for available frequencies. It then reports to the BS which one of the BS's beams (i.e., frequency and direction) resulted in the highest received power. Based on the feedback from the user, the BS then aligns its beam direction to the user device. Then the user device begins beam sweeping using a narrow beam and aligns its beam toward the BS using received signal power measurements.

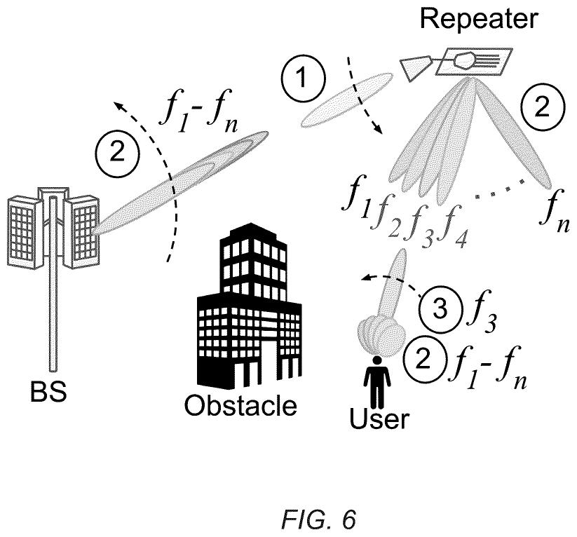

When a passive repeater in accordance with several embodiments of the invention is installed and the LOS path is blocked, the BS and the user device can still try to find the best communication path using the same standard process. FIG. 6 shows the steps in end-to-end beam alignment when a passive repeater is deployed in accordance with some embodiments of the invention. First, the passive repeater aligns its backhaul beam toward the BS. As mentioned previously, the repeater may use its fixed beam antennas (e.g., horn antenna) for its backhaul beams. Hence, the beams of the antennas can be manually adjusted toward the BS. Note, this may a one time process, e.g., during installation, since the BS and repeater location is fixed in many scenarios. Alternative solutions for scenarios where the BS is mobile are described further below.

Next, the BS sweeps its beams and sends synchronization signals in multiple directions and frequency channels (f₁-fₙ). This process can be the same as the standard 5G beam alignment process. However, when the beam of a particular frequency channel is steered in the direction of the repeater, its signal will be forwarded by the repeater to a specific direction based on its frequency. On the other side, the user device also performs standard beam sweeping to find the direction and operating frequencies of the nearby base stations. The user device provides feedback to the BS in the frequencies with the highest signal strength. This feedback is transmitted back to the BS which allows it to determine which beam direction and which frequency provides the best performance for that user device. This will be the direction which aligns the beam of the BS to the repeater, and the frequency which aligns the FSA beam to the user device. This process can be repeated for each user device. Note that in 5G FR2 mmWave bands, the same frequency channel is utilized for both uplink and downlink communication between a user and the BS through Time Division Duplexing (TDD), so a user device does not need to switch beams (frequencies) when transitioning between uplink and downlink communication. Finally, in the third step, the user device performs the standard beam alignment process to find the best direction for its beam. This results in the alignment of the user device's beam toward the repeater. After the beams are aligned, the user device and the BS exchanges additional information to initiate downlink and uplink communication. This entire process and all steps may be done without the BS or user device knowing there is a repeater. The repeater relays the signal between the BS and the user device while the BS and user device perform their standard 5G beam search process. Hence, passive repeaters in accordance with embodiments of the invention can be seamlessly deployed wherever and whenever needed without requiring any cooperation or feedback from the BS or user device.

### Channel Resource Allocation

Passive repeaters in accordance with embodiments of the invention can provide opportunities for more flexible channel resource allocations to the users. In conventional mm Wave networks, when there is a dense number of users in the same area, their network performance drops due to the sharing of the same frequency channel resource. In many embodiments of the invention, this can be addressed by providing partially overlapping channels of different frequencies to cover each area. As previously mentioned, an FSA in accordance with embodiments of the invention shifts its beam continuously with respect to frequency. The scan ratio of an FSA design in certain embodiments is 0.0167 degrees/MHz, meaning that for a channel bandwidth of 100 MHz and 400 MHz, the angle of the beam will shift by 1.67 degrees and 6.67 degrees, respectively. Additionally, the FSA may achieve a 3 dB beam width of around 10 degrees for a single frequency. This means that the beam width of a single frequency is much larger than the amount of angle shift caused by the bandwidth of a frequency channel. Therefore, this design can guarantee not only good coverage for each FSA beam, but also that each user device will be covered by the FSA beams from a few different frequency channels.

Overlapping FSA beams in this way can provide an opportunity to enable more flexible channel resource allocation schemes for the user devices. In particular, the BS can allocate resource blocks based on the quality of each channel relative to the user device location, as well as the occupancy of each channel. This enables more efficient bandwidth utilization of each channel when there are many user devices located in the same area, and ensures higher data rate for each user device. When there are less number of user devices in each area, the overlapping channels also provides the opportunity to improve performance through carrier aggregation which is an existing feature in 5G networks. Finally, in the case of user device mobility, a user device may move from one FSA beam to another beam. As the direction of the FSA beam is determined by the channel frequency, the operating channel of the user device needs to be updated. Note that the BS is able to determine the best frequency channel to allocate to the user based on the continuous exchange of reference signals between the BS and the user device, which are transmitted within the frequency of each channel on a periodic basis. Channel overlap also enables a smoother handoff process when the user device moves between different channels, as the user device can remain connected to a channel while initiating the hand-off procedure with adjacent channels at the same time. In particular, the BS can dynamically adjust the channel resources allocated to a user device when it moves across different FSA beams. With the graceful hand-off process, the BS could schedule resources in advance in adjacent channels. As the repeater is mostly static, beam re-alignment from the basestation to the repeater is rarely needed in the case of user device mobility. In the rare case where the repeater moves (e.g. a drone repeater moving to a different height), the beam realignment between the base station and the repeater can be done with low delay. Beam scanning on the base station can normally take 5 ms (SSB burst), with an interval of 20 ms. Furthermore, the SSB bursts can be sent simultaneously on different frequency channels depending on configuration. Hence beam re-alignment can be done with very low delay when the repeater moves.

### Link Budget Analysis

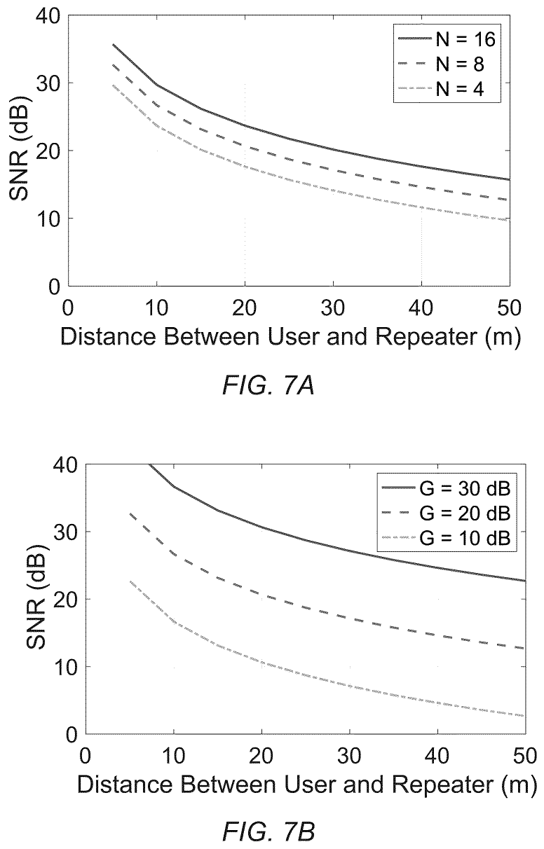

The following analysis considers the downlink, where the base station is the transmitter and the user device is a receiver. However, similar link budget calculations can be done for uplink too. Here, calculate the SNR of the signal at the user device based on the following setup. With a typical 5G base station with an Effective Isotropic Radiated Power (EIRP) of 55 dBm, and a typical mm Wave receiver having a 20 dB antenna gain and noise floor of −88 dBm. Assume the repeater's backhaul antenna and each FSA has 20 dB and 10 dB gain, respectively, based on measurement and simulation results. Consider the repeater's LNA gain and the number of FSAs as variables in the analysis. Finally, assume that the distance of the passive repeater is 200 meters from the base station, which is a reasonable distance to reach an outdoor base station to overcome signal blockage. FIG. 7A shows the SNR of the user device versus distance of the user device from the repeater. Plot the SNR for different number of FSA elements on the repeater where LNA gain is set to 20 dB. As the number of FSA elements increases, repeaters in accordance with embodiments of the invention enable higher SNR and/or longer communication range. However, as the number of FSA elements grows, the design becomes more complex. Hence, a passive repeater with eight FSA elements which is still easy to fabricate in a compact size while it provides SNR of 14 dB even when the user device is 42 meters away from the repeater. Note, this SNR is sufficient to enable more than 240 Mbps data rate for a 100 MHz channel at 28 GHz.

FIG. 7B shows the SNR of the user device versus distance of the user device from the repeater. Plot the SNR for different LNA gain where eight FSA elements are used on the repeater. As the gain of the LNA increases, the communication range of the passive increases too. However, using higher LNA gains increases the power consumption of the repeater. Moreover, very high-gain is difficult since at some point the gain becomes larger than the leakage between the repeater's backhaul and fronthaul beams, causing the self-interference problem. Hence, a passive repeater can be fabricated using 20 dBLNAs. This enables the repeater to achieve good communication range (i.e. SNR of 14 dB even at 42 meters) without having self-interference problem or consuming significant amount of power.

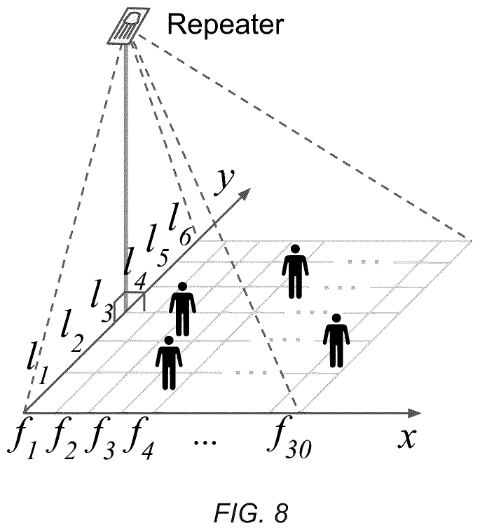

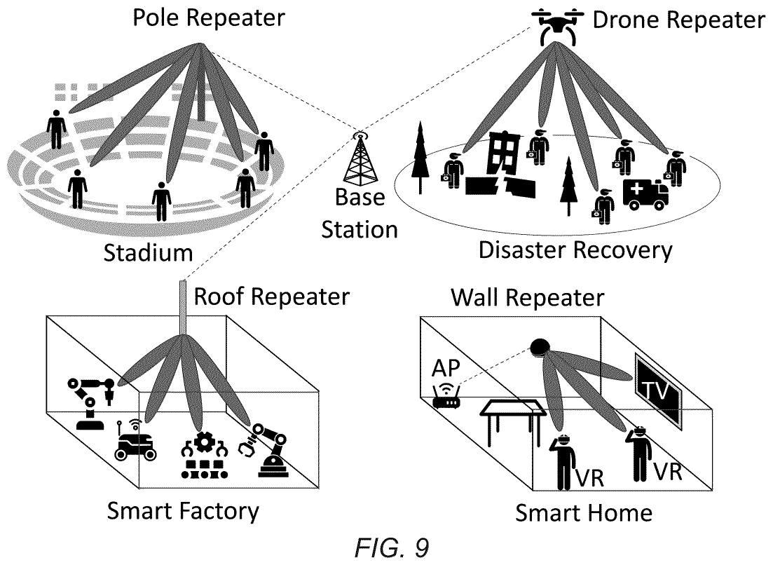

FIG. 8 illustrates an example evaluation setup where the coverage of a passive repeater is divided into 30 cells by 6 cells. FIG. 9 illustrates different environments where a passive repeater may be deployed in accordance with embodiments of the invention.

### Additional Solutions

In embodiments discussed above, a fixed beam horn antenna is used for the backhaul link from the repeater to the base station since in most scenarios the base station is fixed. However, in some scenarios, the position of the base station may change, or the repeater may need to switch to a different base station. There are several possible approaches to address this challenge. First, the horn antennas could be connected to remote controlled gimbals, allowing adjustment to repeater's backhaul beam direction. Alternatively, a passive multi-beam design such as a Rotman lens or directional patch antennas can be used for the backhaul link. This would enable the repeater to receive signals from base stations in varying directions and combine them to the input ports. This approach also enables the entire structure to be fabricated on a single PCB board.

Several embodiments above focus on the downlink communication from the base station to the user since downlink is more important than uplink in most real time applications such as VR/AR. This uni-directional limitation stems from the fact that LNAs used in the design are unidirectional. Hence, to send the channel estimation back to the base station from the user device or/and to support two way communication, bi-directional LNAs should be used, or LNAs can be integrated in both directions for each input port of the Rotman lens. An alternative approach is to deploy two passive repeaters, each dedicated to either downlink or uplink communications.

Further embodiments of the invention enable a bidirectional repeater. Different designs can be used. A repeater may utilize two LNAs in different directions. Two repeaters such as those described above may be utilized in different directions. The uplink may utilize another Rotman lens and FSA pair with a bidirectional LNA in between.

While the above description contains many specific embodiments of the invention, these should not be construed as limitations on the scope of the invention, but rather as an example of one embodiment thereof. It is therefore to be understood that the present invention may be practice otherwise than specifically described, without departing from the scope and spirit of the present invention. Thus, embodiments of the present invention should be considered in all respects as illustrative and not restrictive.

What is claimed is:

1. A passive beamforming wireless signal repeater comprising:
a Rotman lens having a plurality of input ports and a corresponding plurality of output ports, each output port corresponding to an input port, each input port configured to receive a signal from an uplink antenna and apply a phase change to the signal before emitting the signal from the corresponding output port; and
a frequency scanning antenna (FSA) structure comprising a first plurality slots of varying lengths configured to apply a different phase shift at each radiating slot and cause the radiated signals to combine constructively in a certain direction, the FSA configured to receive a signal from the Rotman lens and direct an output signal in a direction determined by the frequency of the signal.

2. The signal repeater of claim 1, wherein the uplink antenna is a horn antenna.

3. The signal repeater of claim 1, wherein the Rotman lens and the FSA are both formed on a PCB substrate.

4. The signal repeater of claim 1, further comprising a low noise amplifier (LNA) connected to each uplink antenna.

5. The signal repeater of claim 4, wherein the LNA is a unidirectional LNA.

6. The signal repeater of claim 4, wherein the LNA is a bidirectional LNA.

7. The signal repeater of claim 1, further comprising a first unidirectional LNA connected to each uplink antenna in an input direction and a second unidirectional LNA in an output direction.

8. The signal repeater of claim 1, further comprising a second plurality of slots on a back surface of FSA opposite of the first plurality of slots.

9. The signal repeater of claim 1, wherein the Rotman lens includes eight input ports.

10. The signal repeater of claim 1, wherein the signal repeater implements a channel matrix of H=GK, where K is the matrix of channels between a base station and the signal repeater's uplink antennas, and is G the matrix of channels between the repeater and the user devices.

11. The signal repeater of claim 1, wherein the base station implements a precoding matrix, to the inverse of GK.

12. The signal repeater of claim 1, wherein the Rotman lens and the FSA combine to direct the output signal in two dimensions.
